(19) United States
(12) Patent Application Publication
(10) Pub. No.: US 2002/0162507 A1
(43) Pub. Date: Nov. 7, 2002

(54) Self-renewing coating for plasma enhanced processing systems

(75) Inventor: Quanyuan Shang, Saratoga, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/846,649

(22) Filed: May 1, 2001

(51) Int. Cl. C23C 16/00

(52) U.S. Cl. 118/723 R; 427/248.1

(57) ABSTRACT

Aspects of the invention generally provide an apparatus and method for providing a contaminate barrier on the surfaces inside the chamber to inhibit the release of contamination within the chamber during processing. In one aspect, the contaminate barrier is self-renewing and may be formed during a process step.

### BACKGROUND OF THE INVENTION

1. Field of the Invention

Aspects of the invention generally relate to an apparatus and method for plasma enhanced processing systems.

2. Background of the Related Art

In the fabrication of flat panel displays, transistors and liquid crystal cells, electronic devices, and other features are formed by depositing and removing multiple layers of conducting, semi-conducting and dielectric materials from a glass substrate. Glass substrate processing techniques include plasma-enhanced chemical vapor deposition (PECVD), physical vapor deposition (PVD), etching, and the like. Plasma processing is particularly well suited for the production of flat panel displays because of the relatively lower processing temperatures required to deposit a good film.

In general, plasma processing involves positioning a substrate on a support member, often referred to as a susceptor or heater, disposed in a vacuum chamber, and striking plasma adjacent to the upper exposed surface of the substrate. The plasma is formed by introducing one or more process gases into the chamber and exciting the gases with an electrical field to cause dissociation of the gases into charged and neutral particles. A plasma may be produced inductively, e.g., using an inductive RF coil, and/or capacitively, e.g., using parallel plate electrodes, or by using microwave energy.

Conventional materials such as aluminum and steel used for fabricating chamber components, i.e., substrate support members, chamber bodies, gas distribution assemblies, shadow frames, and the like, provide good tensile strength, rigidity, and can withstand the process temperatures and gases used to perform the processes such as deposition, etching, cleaning, and the like. Various process gasses used within the chamber during a process (e.g., cleaning, deposition, and the like), may react with the chamber materials and produce unwanted substrate contamination. Unfortunately, the use of higher chamber temperatures for processes such as low-temperature poly-silicon film (LTPS) processing, annealing, and the like, increases the likelihood of substrate contamination. The higher chamber temperature increases the evaporation rate of contaminates within the processing chamber, such as aluminum fluoride (AIF₃), allowing contamination evaporation into the process chamber thereby contaminating the film being deposited. Lower temperatures during the process may help to minimize contamination by keeping the chamber materials from evaporating into the chamber. However, some deposition processes require higher chamber temperatures to provide efficient deposition to occur within the chamber. For example, the formation of LTPS on the substrate is performed at significantly higher deposition temperatures, e.g., about 400° C. to about 500° C., versus less than about 350° C. used in conventional SiN processing. For the most part, the contamination issues have been avoided or minimized by anodizing the chamber materials and the internal components exposed to the process, and/or by using lower process temperatures within the deposition process. Unfortunately, the anodizing process protects the chamber and components for a limited time, until the anodized layer is scratched or worn, or damaged from exposure to the process thereby exposes the chamber materials to the process environment resulting in process contamination.

Therefore, there is a need for a method and apparatus to form a contamination barrier that is self-renewing, capable of minimizing the substrate contamination over a wide range of process temperatures, and provide the chamber and process components with strength and durability.

### SUMMARY OF THE INVENTION

The invention generally provides a method and apparatus for processing substrates including a self-renewing passivation layer that is disposed upon the internal surfaces of a substrate-processing chamber. In one embodiment, the invention provides an apparatus for substrate deposition, comprising a chamber having a body, a bottom, and a lid, a pump to maintain gas pressure within the chamber, a power source coupled to the chamber for establishing a plasma therein, and a substrate support member disposed within the chamber having a substrate supporting surface thereon. A self-renewing passivation layer having a significantly lower rate of evaporation than contaminate compounds produced in the chamber during a processing cycle disposed on one or more of surfaces within the chamber. For example, the chamber walls are preferably coated with the passivation layer.

In another embodiment, the invention provides a method of forming a layer of material on the chamber components, including the steps of delivering a process gas within a chamber, depositing a self-renewing layer having a significantly lower evaporation rate than contaminate compounds formed by the surfaces during processing upon a plurality of surfaces therein.

In one embodiment, the invention provides a method of forming a self-renewing layer of material within a substrate processing chamber to minimize substrate contamination during processing by delivering a process gas into a chamber, depositing a layer upon a plurality of surfaces in the chamber, where the layer includes an evaporation rate less than contaminate compounds within the chamber, and where the layer forms a barrier between the process gas and the surfaces to impede the formation of the contaminates.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a cross-sectional view of a processing chamber of the present invention.

FIG. 2 is a cross-sectional view of a processing chamber of FIG. 1 in a processing position.

FIG. 3 is a partial cross-sectional perspective view of a processing chamber as shown in FIG. 1 in a processing position.

### DETAILED DESCRIPTION OF THE PREFERRED EMBODIMENT

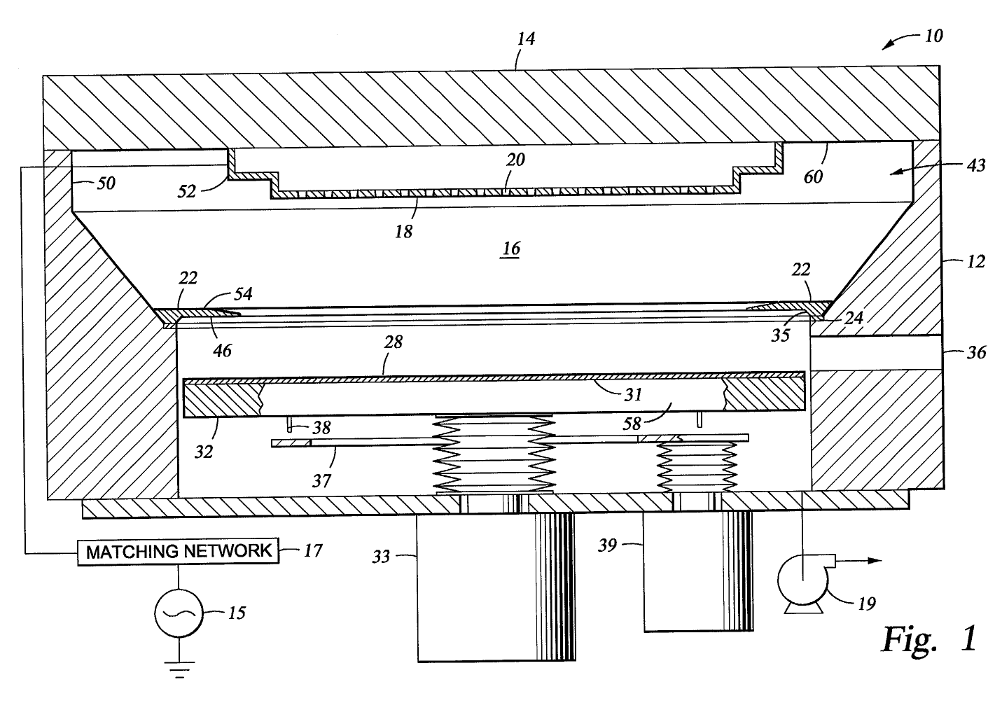

FIG. 1 is a cross-section of one embodiment of a processing chamber 10 of the present invention adapted for processing flat panel displays and substrates that may be used to advantage. The processing chamber 10 comprises a body 12 and a lid 14 disposed on the body 12. The processing chamber 10 defines a cavity that includes a processing region 16. A gas dispersion plate 18, such as a showerhead, is mounted to the lid 14 and defines the upper boundary of the processing region 16. plurality of holes 20 are formed in the gas dispersion plate 18 to allow delivery of process gases therethrough. In one aspect, an RF power supply 15 is coupled through a RF matching network 17 to the gas dispersion plate 18. The gas dispersion plate 18 acts as the chamber anode for the formation of plasma therein. The chamber 10 further includes a movable substrate support member 32, also referred to as a susceptor or heater, raised, or lowered by a motor 33. Conventionally, the substrate support member 32 is heated using restive heaters, lamps, by liquids passed through internal chambers, or other heating devices commonly used in the field of electronic device fabrication. A vacuum pump 19 is coupled to the chamber 10 to maintain a vacuum within the chamber 10. The substrate 28 is introduced into the chamber 10 through an opening 36 formed in the body 12 that is selectively sealed by a slit valve mechanism (not shown). A substrate 28 is positioned on a substrate support surface 31 by a robot blade (not shown). Lift pins 38 (preferably at least four) are slidably disposed through the support member 32 and are adapted to hold the substrate 28 at an upper end thereof during loading and unloading of the substrate 28 from the support member 32. The lift pins 38 are actuatable by an elevator plate 37 and an elevator motor 39 coupled thereto.

In another embodiment, a frame 22, e.g., a shadow frame, comprised of a metal, such as aluminum, anodized aluminum, and ceramic is shown disposed on a support ring 24 of the body 12. The frame 22 is generally used to hold the substrate flat against the support member 32 to minimize substrate deformation during processing, and in one aspect, maximizes the substrate deposition area and minimizes plasma leakage between the support member 32 and the body 12 of the chamber 10. The frame 22 comprises alignment edges 35 and protruding surface 46 extending inwardly to define an inner opening, the inner diameter of which is slightly larger than and conformal with the substrate 28 being processed.

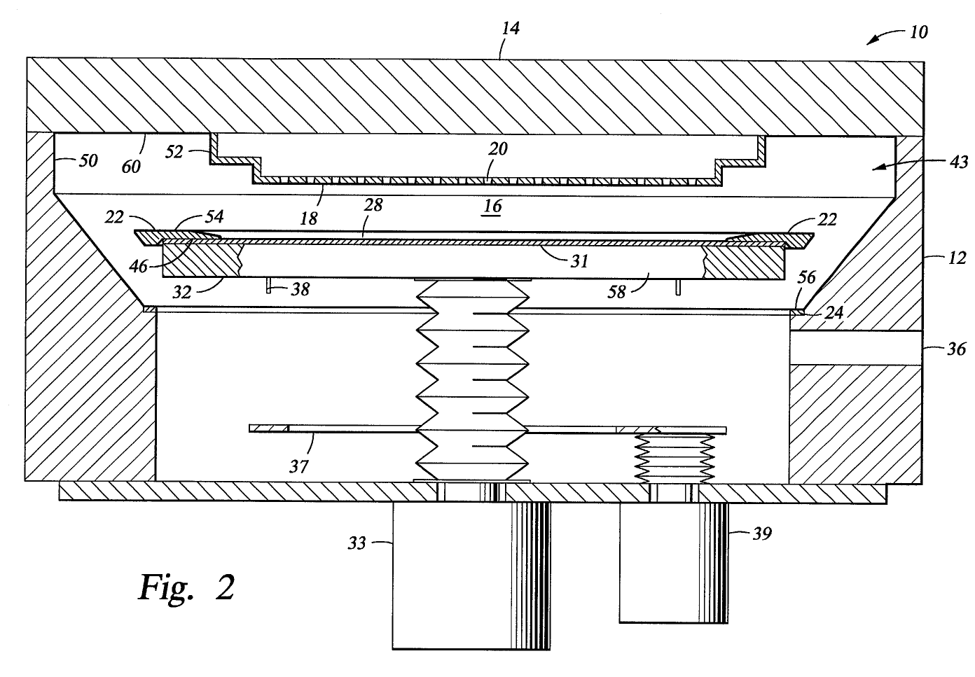

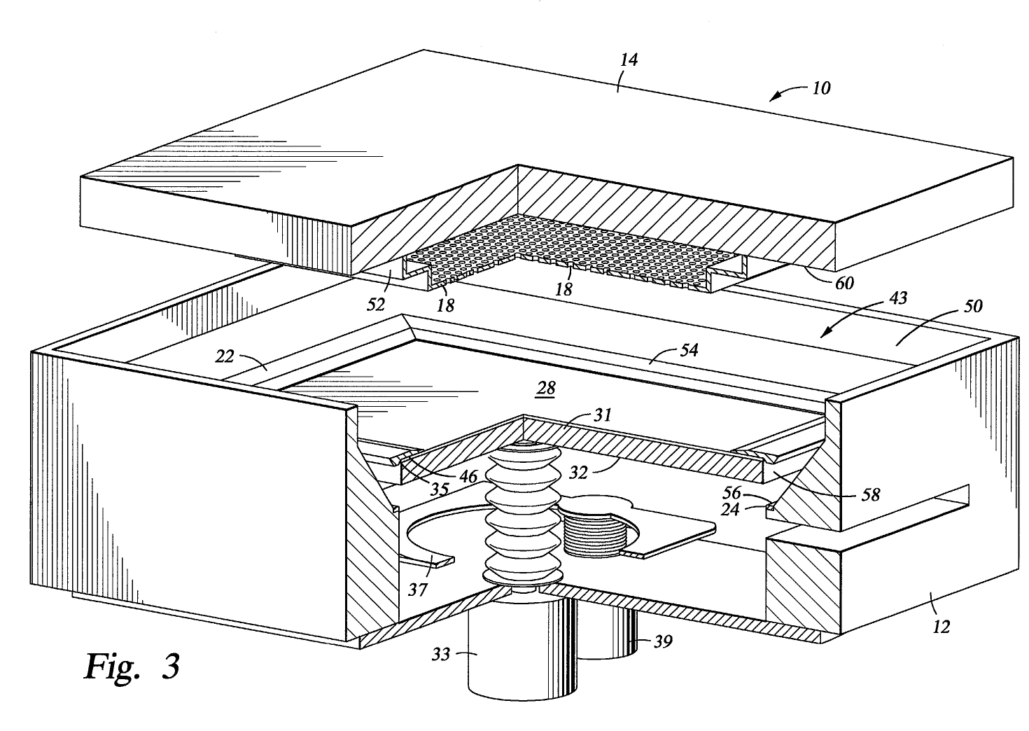

FIG. 2 and 3 illustrate one embodiment of the invention where the support member 32 raised to a processing position lifting the frame 22 from the support ring 24 to define the processing region 16. The support member 32, the body 12, the lid 14, the gas dispersion plate 18, and frame 22 define the internal surfaces 43 comprising a chamber wall surface 50, a dispersion plate surface 52, a protruding surface 46, a frame surface 54, a substrate support surface 31, a support ring surface 56, a support member surface 58, and a lid surface 60, of the chamber 10. The internal surfaces 43 comprise alloys such as aluminum 6061, 5456, and the like containing materials, such as aluminum (Al), silicon (Si), iron (Fe), copper (Cu), manganese (Mn), magnesium (Mg), chromium (Cr), nickel (Ni), zinc (Zn), titanium (Ti) selected in proper proportion to accommodate the substrate-processing environment. Although in some embodiments the aluminum content of the alloy may be between about 90% to about 97%, other percentages are contemplated.

A passivation layer, formed through a chemical reaction with the process gases, is disposed upon and/or integral to the internal surfaces 43 of the chamber 10. The passivation layer includes compounds, such as magnesium fluoride, having a lower vapor pressure at the same temperature, i.e., a lower evaporation rate at the same temperature, than contaminate compounds such as aluminum fluoride produced during a process. Ideally, the passivation layer has a zero evaporation rate. However, evaporation of the internal surfaces 43 occurs because among the molecules near the surface of the material, there are always some molecules with enough heat energy (kinetic energy) to overcome the cohesion of adjacent molecules and escape. Therefore, the lower the evaporation rate of the passivation layer with respect to the contaminate evaporation rate allows the contaminate compounds to evaporate faster from the internal surfaces 43 than the passivation layer, leaving the passivation layer behind on the surfaces 43 to form a contaminate barrier layer. As the formation of the passivation layer may be accomplished during a process step such as cleaning without affecting throughput, the layer may be continually renewed (i.e., self-renewing) to seal any abrasions, i.e., scratches, cuts, nicks, chips, scores, slashes, slices, gashes, gouges, scrapes, and the like, on the internal surfaces 43 that may occur during substrate processing, e.g., a misaligned robot arm inadvertently nicks the chamber wall, or when the chamber is disassembled for cleaning and inspection.

The passivation layer provides a contaminate barrier between the surfaces 43 and the process gasses, thus keeping the chamber surfaces and process gasses from interacting to form the contaminate compounds. For example, in one aspect, at process temperatures at about 350° C. to about 480° C., the passivation layer has a pre-defined vapor pressure of less than about 10⁻⁴ atm (i.e., 10⁻⁴ atmospheres) for contaminates with vapor pressures about greater than about 10⁻⁴ atm.

In other embodiments, the passivation layer compounds and vapor pressures may be selected to accommodate other processes. The amount of substrate contamination is generally a function of temperature and the vapor pressures of the contaminate compounds within the chamber. To establish a reduction in substrate contamination for different process conditions, the passivation layer vapor pressure may be pre-defined less than the vapor pressures of the contaminate compounds. Thus, it is contemplated that a reduction in substrate contamination for different process conditions may result from establishing differential vapor pressures between the passivation layer and the contaminate compounds, where the vapor pressures of the passivation layer are less than the vapor pressures of the contaminate compounds.

Illustratively, magnesium fluoride and an aluminum fluoride contaminate compound were tested to determine the temperature at which evaporation results in a vapor pressure of 10⁻⁴ atm. As tested, magnesium fluoride has a vapor pressure of 10⁻⁴ atm at a temperature of at about 1257° C. and a bond stability of −234 to −238 kcal/molF₂. The aluminum fluoride contaminate compound has a vapor pressure of about 10⁻⁴ atm within the temperature range of 825 to 1145° C., and a bond stability of −206 to −212 kcal/molF₂. Therefore, magnesium fluoride has a lower evaporation rate at the same temperature than the aluminum fluoride contaminate compound, resulting in a lower vapor pressure.

In one embodiment, the passivation layer is formed through a chemical reaction between the process gas and heated internal surfaces 43 where the passivation layer has a lower evaporation rate than the contaminate compounds. The process gas is introduced within the chamber 10 at a pressure of up to about 0.5 Torr, and the internal surfaces are heated between about 250° C. and about 450° C. for a chemical interaction between the process gas and the internal surfaces 43 to form the passivation layer. For example, magnesium fluoride is formed on the internal surfaces 43, e.g., internal surfaces of the chamber 10 and components within the chamber 10 exposed to the process gases, by introducing a process gas comprising fluorine such as nitrogen fluoride (NF₃), CxFy, F2, or other fluorine containing compounds through the gas dispersion plate 18 at a rate of about 0.05 standard liters to about 10 standard liters per minutes. The chamber is held to an operating pressure of up to about 0.5 Torr by vacuum pump 19. Plasma is formed within the processing region 16 using the RF generator 15, exciting the process gas. To activate the precursor gas, a power level value of between about 1,000 W to about 10,000 W may be used. In one aspect, the temperature of the internal surfaces 43 are heated by the support member 32 and the plasma to a temperature of between about 250° C. and about 450° C. Although heating the internal surfaces 43 with the plasma in combination with the heated support member 32 may be preferred in some embodiments, the internal surfaces 43 may be independently heated to the desired temperatures by heaters such as restive heaters, lamps and the like, or by the plasma, or by the support member 32. During the formation of the passivation layer, the fluorine ions react with the aluminum and magnesium within the internal surfaces 43 to form aluminum fluoride and magnesium fluoride, respectively. The formation process temperatures established are sufficient to cause the aluminum fluoride to evaporate quickly, but also established so that the magnesium fluoride evaporates significantly slower than the aluminum fluoride allowing the formation of a passivation layer of magnesium fluoride on the internal surfaces 43. Once the magnesium fluoride is formed to a sufficient thickness of between about 1000 angstroms to about 10,000 angstroms on the internal surfaces 43, fluorine can no longer easily penetrate the internal surfaces 43 to react with the aluminum and other alloy components of the internal surface 33, thereby effectively sealing the internal surfaces 43 from the formation of aluminum fluoride and other contaminates. Subsequently, the evaporated aluminum fluoride contaminate in its gaseous form may be flushed from the chamber 10 using vacuum pump 19, leaving the magnesium fluoride on the internal surfaces 43 and the aluminum fluoride contaminate substantially reduced or eliminated from within the chamber 10.

Although, in one aspect, the internal surfaces 43 are composed of about 3 percent to about 10 percent magnesium to provide a sufficient amount of magnesium reactant to form a sufficiently thick passivation layer of magnesium fluoride, other ratios of magnesium are contemplated. In one embodiment, the magnesium content is sufficient to produce the passivation layer thickness between about 1000 to about 10,000 angstroms, sufficient to seal the internal surfaces 43 and prevent further fluorine penetration into the internal surfaces 43. As the process gas may reach all internal surfaces within the cavity, it is contemplated that the passivation layer may extend to any portion of the chamber 10 where the internal surfaces 43 have exposure to the process gas.

While the foregoing is directed to the preferred embodiment of the present invention, other and further embodiments of the invention may be devised without departing from the basic scope thereof, and the scope thereof is determined by the claims that follow.

What is claimed is:

1. An apparatus for substrate deposition, comprising:
a chamber having a body, a bottom, and a lid;
a pump to maintain gas pressure within the chamber;
a substrate support member disposed within the chamber having a substrate supporting surface thereon; and
a self-renewing layer disposed on one or more of the internal surfaces of the chamber and the surface of the support member wherein the layer has a lower rate of evaporation than contaminate compounds produced in the chamber during a processing cycle.

2. The apparatus of claim 1, further comprising a shadow frame having the layer thereon.

3. The apparatus of claim 1, further comprising a gas dispersion plate having the layer thereon.

4. The apparatus of claim 1, further comprising a process gas within the chamber.

5. The apparatus of claim 1, further comprising a power source coupled to the chamber for establishing a plasma within the chamber.

6. The apparatus of claim 1, wherein the substrate support member comprises a heater.

7. The apparatus of claim 1, wherein the layer is between about 1000 angstroms to about 10,000 angstroms thick.

8. The apparatus of claim 1, wherein the layer comprises an alloy selected from the group of aluminum, silicon, iron, copper, manganese, magnesium, chromium, nickel, zinc, titanium and combinations thereof.

9. The apparatus of claim 8, wherein the alloy comprises at least about between 3% to about 10% magnesium.

10. The apparatus of claim 8, wherein the alloy comprises at least about between 90% to about 97% aluminum.

11. A method of forming a layer of material prior to processing to minimize contamination, comprising:
delivering a process gas into a chamber; and
depositing a self-renewing layer upon a plurality of surfaces in the chamber, the layer comprising a lower evaporation rate than contaminate compounds therein.

12. The method of claim 11, wherein the thickness of the layer is between about 1000 angstroms to about 10,000 angstroms.

13. The method of claim 11, wherein an evaporation rate of the layer results in a vapor pressure of about 10⁻⁴ atm at a surface temperature greater than about 1257° C.

14. The method of claim 11, wherein the layer surfaces comprise magnesium and the process gas comprises fluorine, wherein the process gas is maintained at a pressure of up to about 0.5 Torr.

15. The method of claim 11, wherein the step of depositing the layer upon a plurality of surfaces in the chamber further comprises heating the surfaces to a temperature sufficient to evaporate the contaminate compounds; and wherein the temperature of the surfaces is set to minimize the evaporation of the layer.

16. The method of claim 15, wherein the evaporation rate of the contaminates results in a vapor pressure of about 10⁻⁴ atm at a surface temperature between about 825° C. to about 1145° C.

17. The method of claim 11, wherein the step of depositing further comprises heating the surfaces with a temperature sufficient to establish a reaction between the surface and the process gas to form the layer.

18. The method of claim 17, further comprising heating the surfaces with a heated support member disposed in the chamber.

19. The method of claim 17, wherein the process gas is selected from the group of F₂, NF₃, CₓF_{y}, and combinations thereof.

20. The method of claim 17, wherein the surfaces are selected from the group of aluminum, silicon, iron, copper, manganese, magnesium, chromium, nickel, zinc, titanium, and combinations thereof.

21. The method of claim 17, wherein the surfaces comprises at least about 90% to about 97% aluminum.

22. The method of claim 17, wherein the surfaces comprises at least about 3% to about 10% magnesium.

23. A method of forming a layer of material within a substrate processing chamber to minimize substrate contamination during processing, comprising:
delivering a process gas into a chamber; and
depositing a self-renewing layer upon a plurality of surfaces in the chamber, the layer comprising an evaporation rate less than contaminate compounds therein, wherein the layer forms a contaminate barrier about 1000 angstroms to 10,000 angstroms thick between the process gas and the surfaces to impede the formation of the contaminate compounds therein.

24. The method of claim 11, wherein the layer surfaces comprise magnesium and the process gas comprises fluorine, wherein the process gas is maintained at a pressure of up to about 0.5 Torr.

25. The method of claim 23, wherein the evaporation rate of the contaminate compounds results in a vapor pressure of about 10⁻⁴ atm at a surface temperature between about 825° C. to about 1145° C.

26. The method of claim 23, wherein the step of depositing the layer upon a plurality of surfaces in the chamber further comprises heating the surfaces to a temperature sufficient to evaporate the contaminate compounds; and wherein the temperature of the surfaces is set to minimize the evaporation of the layer.

27. The method of claim 26, further comprising heating the surfaces with a heated support member disposed in the chamber.

28. The method of claim 26, wherein the process gas is selected from the group of F₂, NF₃, CₓF_{y}, and combinations thereof.

29. The method of claim 26, wherein the surfaces are selected from the group of aluminum, silicon, iron, copper, manganese, magnesium, chromium, nickel, zinc, titanium, and combinations thereof.

30. The method of claim 26, wherein the surfaces comprises at least about 90% to about 97% aluminum.

31. The method of claim 26, wherein the surfaces comprises at least about 3% to about 10% magnesium.
